(19) United States
(12) Patent Application Publication
(10) Pub. No.: US 2014/0264847 A1
(43) Pub. Date: Sep. 18, 2014

(54) SEMICONDUCTOR DEVICE

(71) Applicant: Kabushiki Kaisha Toshiba, Tokyo (JP)

(72) Inventor: Makoto TAKAHASHI, Kanagawa (JP)

(73) Assignee: Kabushiki Kaisha Toshiba, Tokyo (JP)

(21) Appl. No.: 14/017,223

(22) Filed: Sep. 3, 2013

(30) Foreign Application Priority Data
Mar. 14, 2013 (JP) 2013-052007

(51) Int. Cl. H01L 23/00; H01L 25/00

(52) U.S. Cl. CPC H01L 24/14; H01L 25/00; H01L 24/11
USPC 257/737; 438/613

(57) ABSTRACT

A semiconductor device includes a plurality of electrodes disposed on a surface in a first column and a second column parallel to the first and separated by a first distance. The adjacent electrodes in the first column are spaced from each other by at least a second distance. Adjacent electrodes in the second column are spaced from each other by at least a third distance. The distance between adjacent columns is not equal to the spacing distance of electrodes in the first column and the electrodes form a staggered lattice in which no electrode in the first column is aligned perpendicularly with any electrode in the second column.

### CROSS-REFERENCE TO RELATED APPLICATION

This application is based upon and claims the benefit of priority from Japanese Patent Application No. 2013-052007, filed Mar. 14, 2013, the entire contents of which are incorporated herein by reference.

### FIELD

Embodiments described herein relate generally to a semiconductor device.

### BACKGROUND

Recently, there has arisen the need for improvement in data transfer speed between a logic circuit and a memory circuit and an increase in memory capacity. In reply to this need, a stacked semiconductor device of Chip on Chip (CoC) structure, in which a plurality of semiconductor chips is stacked in one package, has been adopted. In the CoC structure, if the stacked semiconductor chips are directly bonded using fine bumps having a diameter of about 30 μm (hereinafter, referred to as a “micro bump”), multipoint connection in the thousands can be provided between the stacked chips. The multipoint connection provided by using micro bumps makes it possible to expand the bus width and improve the transmission speed between stacked chips.

In a stacked semiconductor device, micro bumps are generally arranged in a bump area in a square lattice-shaped matrix including m rows and n columns of micro bumps. But in keeping with the trend of downsizing semiconductor chips, the bump area has to decrease in size concomitantly. However, when the size of the bump is decreased, the relative distance (pitch) between the micro bumps has to be narrowed or the size of a micro bump has to be downsized if the same total number of micro bumps is to be provided.

Accordingly, it has become difficult to further reduce the pitch between micro bumps and the bump size, and the bump area size using the approaches of the related art.

### DESCRIPTION OF THE DRAWINGS

FIG. 1 is a schematic plan view of a semiconductor device according to a first embodiment.

FIG. 2 is a schematic plan view depicting an alignment of micro bumps in a bump area.

FIG. 3 is a table showing a relationship between the interior angle of a triangle formed by the micro bumps and the area of the same triangle.

FIG. 4 is a schematic view depicting an example of a chip-on-chip stacked semiconductor device structure in which semiconductor chips are bonded with micro bumps.

FIG. 5 is a schematic cross section depicting a cross section taken along the line A-A′ of the stacked semiconductor device depicted in FIG. 4.

FIG. 6 is a schematic plan view depicting a possible arrangement of a bump area, a spare bump area, and a repair control unit according to a second embodiment.

FIG. 7 is a schematic plan view depicting another possible arrangement of a bump area, a spare bump area, and a repair control unit according to the second embodiment.

### DETAILED DESCRIPTION

In general, according to one embodiment, a semiconductor device includes a plurality of electrodes disposed on a surface in a first column and a second column that is parallel to the first column and spaced at a first distance from the first column, each electrode in the first column is spaced from adjacent electrodes in the first column by at least a second distance, each electrode in the second column is spaced from adjacent electrodes in the second column by at least a third distance. The second distance is not equal to first distance, and the plurality of electrodes form a staggered lattice in which no electrode in the first column is aligned with any electrode in the second column on a line perpendicular to both the first column and the second column.

In general, according to another embodiment, a semiconductor device includes an electrode region formed on one surface of a semiconductor chip and a plurality of electrodes arranged on the electrode region in a staggered lattice shape. With respect to electrode columns each including the plurality of electrodes aligned, a distance between the adjacent electrode columns is different from a distance between the adjacent electrodes that are aligned in the same electrode column.

Hereinafter, example embodiments will be described with reference to the drawings.

### First Embodiment

FIG. 1 is a schematic plan view of a semiconductor device 1 according to a first embodiment. As illustrated in FIG. 1, a circuit region including a logic circuit, memory circuit, or the like is formed, for example, on a semiconductor substrate made of single silicon crystal. On the surface of the semiconductor device 1, a bump area 2 with a plurality of micro bumps 3 is provided as an electrode region. In the bump area 2, many micro bumps 3 having a diameter of, for example, about 30 μm are formed. The micro bumps 3 are electrically connected to the circuit region formed on the semiconductor device 1. The electrical connection between micro bumps 3 and the circuit region may be made via TSV (Through Silicon Via, silicon through-hole electrode) technique or the like. The electrical connections made via the TSV (or the like) may be for external electrode connections for use in power supply and signal input and output.

Arrangement of the micro bumps in the bump area 2 is depicted in FIG. 2. FIG. 2 is a schematic plan view depicting one example of the arrangement of the micro bumps 3 in the bump area 2. As illustrated in FIG. 2, a plurality of micro bumps 3 is arranged in a staggered lattice within the bump area 2. Specifically, several bump columns each including a plurality of micro bumps 3 arranged in the Y direction at a predetermined pitch (Ya) are provided. The bump columns may be conceptually numbered as a first column, a second column, etc. starting from the depicted left-hand edge of the bump area 2. Even numbered bump columns have a bump pattern that is offset from the bump pattern in the odd numbered bump columns by a predetermined distance (for example, Ya/2) in the Y direction. Although in this example the even numbered bump columns are offset, the odd numbered bump could instead be offset from the even numbered bump columns.

The pitch between the adjacent columns is not shorter than the minimum bump pitch. For example, the pitch (Xa) between the micro bump 3a arranged in the first column and the micro bump 3c arranged in the second column is set at the minimum bump pitch Here, the minimum bump pitch means the shortest pitch (e.g., distance between nominal center points of adjacent bumps) at which the micro bumps can be formed without causing a bump formation failure or device malfunction (for example, the adjacent micro bumps clump together).

Next, the specific arrangement of the micro bumps 3 in the adjacent columns will be described using three micro bumps 3a, 3b, and 3c.

The micro bumps 3a, 3b, and 3c are arranged in this embodiment so that the sum total of the interior angle θa with a vertex at center point of micro bump 3b and the interior angle Ob with a vertex at center point of micro bump 3a is in the range of 90 degree to 120 degree, inclusively. Further, the micro bumps 3a, 3b, and 3c are arranged so that every pitch (namely, each length of all sides of a triangle) including the pitch between the micro bump 3a and the micro bump 3b, the pitch between the micro bump 3a and the micro bump 3c, and the pitch between the micro bump 3b and the micro bump 3c is not be shorter than the minimum bump distance.

In FIG. 3, the bump density for micro bumps arranged in a square lattice-shaped matrix is compared with the bump density for micro bumps arranged in a staggered lattice-shape matrix.

FIG. 3 further shows the relation between the interior angle θa of a triangle formed by the micro bumps 3a, 3b, and 3c and the resulting area of the triangle.

In the table shown in FIG. 3, column “Ya” values correspond to the pitch between the micro bump 3a and the micro bump 3b. In the table, column “Xa” values correspond to the pitch between the micro bump 3a and the micro bump 3c.

Here, the bump density is compared by comparing the area of the triangle formed by the three micro bumps 3a, 3b, and 3c. Namely, the same total number of bumps may be arranged in a smaller area when the area of the triangle is smaller; therefore, the smaller the area of the triangle the higher the bump density.

When the micro bumps are arranged in a square lattice-shaped matrix, for example, the two adjacent bump columns are aligned without deviating either in the X direction or in the Y direction with the interior angle θb of 90 degrees and the interior angle θa of 45 degrees in FIG. 2. Namely, the micro bump in a square lattice shape forms an isosceles right triangle. Further, the pitch Ya between the micro bump 3a and the micro bump 3b and the pitch Xa between the micro bump 3a and the micro bump 3c are both set at the minimum bump pitch. When the minimum bump pitch is, for example, 20 μm, the area of the triangle formed by the micro bumps 3a, 3b, and 3c becomes 200 μm², as shown in the first row of the table in FIG. 3.

Next, with the pitch Ya between the micro bump 3a and the micro bump 3b and the pitch Xa between the micro bump 3a and the micro bump 3c remaining as the minimum bump pitch, the even numbered bump column is gradually deviated from the odd numbered bump column in the Y direction, and then a change in the area of the triangle is determined. As the deviation amount in the Y direction gets larger as the interior angle θa gets larger, the interior angle θa is increased by every one degree from 45 degrees and the area of the triangle is calculated in every case.

When the interior angle θa is increased from 45 degrees to 60, the area of the triangle is reduced from 200 to 173.21, as indicated in FIG. 3. According to this, the area of the triangle is determined and then it is found that when θa is 60 degree with the pitch Ya remaining the minimum bump pitch, in other words, when the triangle formed by the three micro bumps 3a, 3b, and 3c is an equilateral triangle, the area becomes the minimum. According to this arrangement, the micro bumps 3 may be arranged at a higher density than in the case of arranging the micro bumps in the square lattice-shaped matrix. Accordingly, it is found that the area of the bump area 2 necessary for arranging the same number of the micro bumps 3 may be reduced.

The distance Xb between the odd numbered bump column and the even numbered bump column is represented by the following formula (I).

[Formula 1]

$$Xb = \frac{\sqrt{4 {Xa}^{2} - {Ya}^{2}}}{2} \qquad ( 1 )$$

Where, Xb<Ya. Accordingly, even if the Y direction of the bump area 2 gets longer by Ya/2, the X direction may be significantly reduced and the bump density may be enhanced.

Next, the case in which the pitch between the micro bump 3a and the micro bump 3c and the pitch between the micro bump 3b and the micro bump 3c are both the minimum bump pitch, namely, the case in which the triangle formed by the three micro bumps 3a, 3b, and 3c is an isosceles triangle, will be described. In this case, it becomes an isosceles triangle with the interior angle θa and the interior angle θb are defined as a base angle and the angle formed by the micro bumps 3a, 3c, and 3b is defined as an apex angle. Interior angle θa and the interior angle θb are in this embodiment, by definition, equal to each other. The total of the base angles θa and θb is larger than the apex angle. Namely, it becomes the isosceles triangle with the total of the base angles θa and θb is in the range of 90 degrees to 120 degrees inclusively. The pitch (pitch Ya between the micro bump 3a and the micro bump 3b in FIG. 2) between the two micro bumps 3 arranged in series (adjacently) in the same bump column, which is the bottom line of this isosceles triangle, can be larger than the minimum bump pitch. In this case, however, the distance (Xb) between the odd numbered bump column and the even numbered bump column becomes shorter than the above mentioned formula (1), and therefore, the area of the triangle formed by the micro bumps 3a, 3b, and 3c becomes smaller than in the case of the arrangement of the square lattice-shaped matrix. Therefore, although the length of the bump area 2 in the Y direction becomes longer, the length in the X direction becomes shorter and the area of the bump area 2 as a whole may be reduced.

Even when either the pitch between the micro bump 3a and the micro bump 3c or the pitch between the micro bump 3b and the micro bump 3c is larger than the minimum bump pitch, namely, even when the triangle formed by the three micro bumps 3a, 3b, and 3c is a scalene triangle, the bump columns are arranged so that the total of the interior angle θa and the interior angle θb may be set in the range of 90 degrees to 120 degrees inclusively (namely, in the range where the total of the interior angle θa and the interior angle θb is larger than the remaining interior angle), and therefore the area of the triangle formed by the micro bumps 3a, 3b, and 3c may be smaller than that in the case of the square lattice-shaped matrix arrangement.

When the pitch between the micro bumps 3a and 3b is defined as the bottom line and the length of the line perpendicularly extending from the micro bump 3c to the bottom line is defined as a height, hence to form a triangle, the following condition is satisfied. First, the bottom line is longer than the height. Second, the height is shorter than the minimum bump pitch. Third, the total of the interior angles θa and θb is larger than the interior angles ∠3a, 3c, and 3b. Of the three sides, at least one side is preferably the minimum bump pitch. Namely, if a triangle satisfies the above conditions, any shape will do. For example, an equilateral triangle, an isosceles triangle, or a scalene triangle will do.

As mentioned above, according to the embodiment, when many micro bumps 3 are arranged on the surface of a semiconductor substrate in a matrix shape, the even numbered bump columns are deviated from the odd numbered bump columns by a predetermined distance, into a staggered lattice shape. According to this, the distance between the bump columns may be reduced while maintaining the pitch of the micro bumps 3 as not shorter than the minimum bump pitch, thereby improving the bump density. Therefore, it is possible to reduce the area of the bump area 2 for forming the micro bumps 3, without decreasing the number of the micro bumps 3. Alternatively, it is possible to form a greater number of micro bumps 3 if the same bump area size is used.

Further, according to the embodiment, only the arrangement of the micro bumps 3 has only to be changed, compared with the conventional semiconductor device; therefore, the improved bump density may be provided at a low cost, and the area of the bump area 2 can be reduced.

Next, as illustrated in FIGS. 4 and 5, in the stacked semiconductor device of the CoC structure, an example of directly bonding stacked semiconductor chips via the micro bumps will be described.

FIG. 4 is a schematic view depicting a stacked semiconductor device of the CoC structure. FIG. 5 is a schematic cross sectional view depicting the cross section taken along the line A-A′ of the stacked semiconductor device in FIG. 4.

FIG. 4 shows one stacked semiconductor device having three stacked semiconductor chips 1, 1a, and 1b. In the semiconductor chip 1, the bump area 2 with many micro-bumps 3 formed therein is provided on a surface opposite to the semiconductor chip 1a. Many micro bumps are similarly formed on the respective facing surfaces of the semiconductor chips 1a and 1b.

As illustrated in FIG. 5, each TSV (Through Silicon Via, silicon through electrode) 7 is provided in the semiconductor chip 1a disposed between semiconductor chip 1 and semiconductor chip 1b. On the surface of the TSV, the micro bump 3 is formed as a connection point for joining to the other semiconductor chip. Accordingly, the semiconductor chip 1a has the micro bumps 3 formed on the front and back sides of the substrate. The semiconductor chip 1b positioned in the lowest layer has micro bumps 3 formed on the surface opposite to the semiconductor chip 1a. Thus, in the case of forming a stacked semiconductor device, the micro bumps 3 used as the connection points of the TSVs provided on the semiconductor chip are arranged in a staggered lattice shape as described above to reduce the bump area 2. As the result, downsizing of the semiconductor device may be achieved.

### Second Embodiment

In the above mentioned semiconductor device 1 of the first embodiment, the bump area 2 with a necessary number of micro bumps 3 for a connection to another semiconductor device is formed. In a second embodiment, a spare bump area, for providing spare micro bumps to be used as substitutions when a defect occurs in the micro bumps 3 formed in the bump area 2, is formed as an auxiliary electrode region. The semiconductor device 1 of this embodiment has the same component elements of the first embodiment, but includes a spare bump area and a repair control unit; therefore, the same reference numerals corresponding to the same components are used and the associated description is omitted.

Structure of the bump area 2, a spare bump area 4, and a repair control unit 5 in the semiconductor device 1 of the embodiment is depicted in FIG. 6. FIG. 6 is a schematic plan view depicting the bump area 2, the spare bump area 4, and the repair control unit 5 according to the second embodiment. As illustrated in FIG. 6, in the semiconductor device 1 of the second embodiment, a spare bump area 4 is formed on the periphery of the bump area 2. In the spare bump area 4, spare micro bumps 31 are arranged as auxiliary electrodes. The spare micro bumps 31 are arranged in a staggered lattice shape similar to the micro bumps 3 in bump area 2. Namely, a plurality of bump columns each including a micro bump 31 or a plurality of micro bumps 31 spaced at a constant pitch are provided. The placement of the bumps in the even numbered bump columns are shifted from the placement of the bumps in the odd numbered bump columns by a predetermined distance in the column direction. As similar to describe for bump area 2, by arranging the spare micro bumps 31 in a staggered lattice shape, the spare bump area 4 size may be reduced.

When a defect happens in the formation or placement of micro bumps 3, the repair control unit 5 is provided in the periphery of the bump area 2, to correct the faulty/failed connection by using a spare micro bump 31 instead of the malfunctioning micro bump 3 (designated micro bump 3′ in FIG. 6). For example, when a defect happens in the micro bump 3,′ which, as depicted in FIG. 6, is in the second column from the left and in the second row from the top, the repair control unit 5 switches the circuit using the spare micro bump 31 provided on the extending line from the column of the relevant micro bump 3′ (in the second column from the left) as the substitution of the micro bump 3′ hence to save the circuit.

As mentioned above, according to the embodiment, the spare micro bump 31 for realizing a redundant function is arranged just in case of a defect happening in the micro bumps 3 within the micro bump area 2. By arranging the micro bumps 31 in a staggered lattice shape, the bump density may be improved, without changing the pitch between the micro bumps 31 and the total number thereof, compared with the case of arranging them in a square lattice shape. Therefore, the spare bump area 4 may be reduced.

In the periphery of the bump area 2, the spare bump area 4 may be formed only on one side in the column direction or in the row direction, as illustrated by a solid line in FIG. 6, alternatively, it may be formed in away of surrounding the bump area 2, as illustrated by a dotted line. In short, the spare bump area 4 may be formed in a necessary portion in the periphery of the bump area 2. Thus, if bump area 2 is a rectangular shape (which is not a requirement), the spare bump area may be on any one side, any two sides, any three sides, or all sides. Similarly, depending on the disposition of the spare bump area 4 and the scale of repair capability desired, the repair control unit 5 may be formed in a necessary portion in the periphery of the bump area 2.

Further, in an example shown in FIG. 6, the number of the spare micro bumps 31 is the same as the number of the columns of the micro bumps 3; however, the number of spare micro bumps 31 and columns of micro bumps 3 are not required to be same number. For example, as illustrated in FIG. 7, the spare micro bumps 31 may be arranged only on the extending line of the even numbered column of the micro bumps 3. FIG. 7 is a schematic plan view for use in describing another structure of the bump area 2, the spare bump area 4, and the repair control unit 5 according to the second embodiment. In this case, since the total number of the spare micro bumps 31 becomes half of the example shown in FIG. 6, the spare bump area 4 size may be further reduced. By arranging the spare micro bumps 31, as illustrated in FIG. 7, symmetry after repair may be secured.

Further, although the description has been made by way of example of the stacked semiconductor device of the CoC structure, it is not restricted to this but it may be applied to the electrode arrangement between a semiconductor chip and a package substrate and between the package substrates.

Each unit in the specification is a conceptual form corresponding to each function of the embodiments; it is not necessarily in a one-to-one correspondence with specified hardware or software routine. Accordingly, in this specification, the embodiments have been described assuming a virtual circuit block (unit) having each function of the embodiments.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a plurality of electrodes disposed on a surface in a first column and a second column that is parallel to the first column and spaced at a first distance from the first column, each electrode in the first column spaced from adjacent electrodes in the first column by at least a second distance, each electrode in the second column spaced from adjacent electrodes in the second column by at least a third distance, wherein
the second distance is not equal to first distance, and the plurality of electrodes form a staggered lattice in which no electrode in the first column is aligned with any electrode in the second column on a line perpendicular to both the first column and the second column.

2. The device according to claim 1, wherein the surface is a surface of a semiconductor chip.

3. The device according to claim 1, wherein at least one electrode in the plurality of electrodes is a micro bump electrode.

4. The device according to claim 1, wherein at least one electrode in the plurality of electrodes is electrically connected to an electrode disposed on a second surface.

5. The device of claim 1, wherein the surface is a surface of a first semiconductor chip and at least one electrode of the plurality is electrically connected to an electrode on a surface of a second semiconductor chip that is stacked on the first semiconductor chip.

6. The device according to claim 1, further comprising:
at least one auxiliary electrode disposed on the surface and aligned with at least one of the first column and the second column.

7. The device according to claim 6, wherein the first column has two or more auxiliary electrode aligned therewith.

8. The device according to claim 6, wherein the first column has one auxiliary electrode aligned therewith and the second column has another auxiliary electrode aligned therewith.

9. The device according to claim 6, wherein only the first column has at least one electrode aligned therewith.

10. The device according to claim 6, wherein the plurality of electrodes is disposed within an electrode region on the surface and the at least one auxiliary electrode is disposed in an auxiliary electrode region on the surface.

11. The device according to claim 10, wherein the auxiliary electrode region is at an end of the first column and perpendicular to the first column.

12. The device according to claim 10, wherein the auxiliary electrode region is parallel to the first column.

13. The device according to claim 1, wherein at least one electrode in the plurality of electrodes is connected to a through-silicon-via (TSV).

14. The device according to claim 1, wherein the first distance is less than the second distance, and the second distance is equal to the third distance.

15. The device according to claim 1, wherein the first distance is less than a minimum pitch distance at which the electrodes of the plurality of electrodes can be placed without defect.

16. A semiconductor device, comprising:
an electrode region on one surface of a semiconductor chip;
an auxiliary electrode region on the one surface and adjacent to the electrode region;
a plurality of micro bumps disposed in the electrode region in a plurality of columns; and
a plurality of spare micro bumps disposed in the auxiliary electrode region, wherein
a distance between any two adjacent columns in the electrode region is less than a distance between micro bumps that are adjacent to each other within any one column in the electrode region, and
any two micro bumps adjacent to each other in a first column in the plurality of columns and a micro bump in a second column in the plurality of columns that is adjacent to the first column form vertices of an isosceles triangle in which each angle is less than 90 degrees.

17. The semiconductor device according to claim 16, wherein spare micro bumps are aligned with each column in the plurality of columns.

18. The semiconductor device according to claim 16, wherein spare micro bumps are aligned only with every other column in the plurality of columns.

19. A method of fabricating a semiconductor device, comprising:
obtaining a substrate having a surface;
placing a plurality of electrodes on the surface in a first column and a second column that is parallel to the first column and spaced at a first distance from the first column, each electrode in the first column spaced from adjacent electrodes in the first column by at least a second distance, each electrode in the second column spaced from adjacent electrodes in the second column by at least a third distance,
wherein the second distance is not equal to the first distance and the plurality of electrodes form a staggered lattice in which no electrode in the first column is aligned with any electrode in the second column on a line perpendicular to both the first column and the second column.

20. The method of claim 19, further comprising:
placing an auxiliary electrode on the surface, the auxiliary electrode aligned with one of the first column and the second column.
